(19) United States
(12) Patent Application Publication
(10) Pub. No.: US 2009/0298229 A1
(43) Pub. Date: Dec. 3, 2009

(54) FLIP CHIP PACKAGE AND METHOD FOR MANUFACTURING THE SAME

(76) Inventors: Seong Cheol KIM, Gyeongsangnam-do (KR); Min Suk SUH, Seoul (KR)

Correspondence Address: LADAS & PARRY LLP, 224 SOUTH MICHIGAN AVENUE, SUITE 1600, CHICAGO, IL, 60604, US

(21) Appl. No.: 12/538,234

(22) Filed: Aug. 10, 2009

Related U.S. Application Data
(62) Division of application No. 11/778,253, filed on Jul. 16, 2007.

(30) Foreign Application Priority Data
Jun. 18, 2007 (KR) 10-2007-0059313

(51) Int. Cl. H01L 21/60

(52) U.S. Cl. 438/108; 257/E21.511

(57) ABSTRACT

A flip chip package realizes a fine pitch and improves the reliability of a bump joint and a method for manufacturing the same. The flip chip package includes a printed circuit board having a plurality of electrode terminals on one surface thereof; a semiconductor chip located on the printed circuit board in a face-down type and having a plurality of bonding pads; conductive polymers for electrically and mechanically connecting the bonding pads of the semiconductor chip and the electrode terminals of the printed circuit board with each other; and an encapsulant for molding one surface of the printed circuit board including the conductive polymers and the semiconductor chip.

### CROSS-REFERENCE TO RELATED APPLICATIONS

The present application claims priority to Korean patent application number 10-2007-00 filed on Jun. 20, 2007, which is incorporated herein by reference in its entirety.

### BACKGROUND OF THE INVENTION

The present invention relates to a flip chip package, and more particularly, to a flip chip package which realizes a fine pitch and improves the reliability of a bump joint and a method for manufacturing the same.

As the various electric or electronic products trend moves toward miniaturization, researchers have actively been required to mount an increasing number of semiconductor chips to a printed circuit board while having a limited size to accomplish miniaturization and high capacity. Further, the size of a semiconductor package mounted to a printed circuit board has also been decreased.

For example, a chip size package has been suggested in the art, in which the size of a semiconductor chip is greater than 80% of the overall size of the package. Because the chip size package has advantages in terms of light weight, slimness, compactness and miniaturization, it has been developed into various shapes.

Meanwhile, typical semiconductor packages and some of chip size packages are mounted to printed circuit boards by a soldering method which uses lead frames. However, while the soldering method which uses lead frames provides advantages in terms of processability and reliability, since the length of an electric signal transmission path between the semiconductor chip and the printed circuit board increases, electric characteristics are likely to be degraded.

Therefore, in order to minimize the length of an electric signal transmission path between the semiconductor chip and the printed circuit board, a flip chip package which uses bumps has been disclosed in the art.

FIG. 1 is a cross-sectional view illustrating a flip chip package according to the conventional art.

Referring to FIG. 1, a flip chip package 100 has a configuration in which a semiconductor chip 102 and a printed circuit board 105 are mechanically bonded to each other and electrically connected with each other by means of bumps 104.

In the flip chip package 100, since electric signal transmission between the semiconductor chip 102 and the printed circuit board 105 is implemented only by the medium of the bumps 104, a signal transmission path is shortened, and therefore, advantages are provided in terms of electric characteristics.

In FIG. 1, the unexplained reference numeral 106 and 107 respectively designate underfill material and solder balls, and the unexplained reference numeral 108 designates an encapsulant.

However, the conventional flip chip package encounters several problems in that the semiconductor chip and the printed circuit board are mechanically and electrically connected with each other using the solder bumps which are a metallic compound containing metal.

In detail, due to formation of an intermetallic compound which can be created by coupling of metallic materials such as the solder bumps and the bonding pads of the semiconductor chip or such as the solder bumps and the electrode terminals of the printed circuit board, the reliability of a bump joint is likely to be deteriorated. Also, when conducting a flip chip bonding process which is relatively complicated, since the above-described materials are bonded to each other, processing defects can occur. In addition, if defects occur, manufacturing cost increases since another process for removing the defects must be added. a.

Additionally, when bonding the solder bumps to the bonding pads of the semiconductor chip or the solder bumps to the electrode terminals of the printed circuit board, a process must be added due to use of a flux, by which other problems are caused in manufacturing processes because the bonding characteristics between the metallic materials are poor.

Furthermore, when attaching the semiconductor chip to the printed circuit board, difficulties occur in the manufacture of a flip chip package which requires a fine pitch because crushing or short-circuiting of the solder bumps, which are made of a metallic compound, is likely to occur.

### SUMMARY OF THE INVENTION

An embodiment of the present invention is directed to a flip chip package which improves the reliability of a bump joint and a method for manufacturing the same.

Another embodiment of the present invention is directed to a flip chip package which alleviates difficulties in manufacturing processes and a method for manufacturing the same.

Still another embodiment of the present invention is directed to a flip chip package which realizes a fine pitch and a method for manufacturing the same.

In one aspect, a flip chip package comprises a printed circuit board having a plurality of electrode terminals on one surface thereof; a face-down semiconductor chip located on the printed circuit board and having a plurality of bonding pads; conductive polymers for electrically and mechanically connecting the bonding pads of the semiconductor chip to the electrode terminals of the printed circuit board; and an encapsulant for molding one surface of the printed circuit board including the conductive polymers and the semiconductor chip.

The conductive polymers are formed to have a size of 5˜500 μm, preferably, 50˜200 μm.

The conductive polymers contain conductive particles.

The conductive polymer comprises one selected from the group consisting of organic sulfonic acid, thiophene, pyrrole, a derivative of thiophene, a derivative of pyrrole polyethylene dioxythiophene, and polystyrene sulfonate.

Solder balls are attached to a lower surface of the printed circuit board.

In another aspect, a method for manufacturing a flip chip package comprises the steps of forming nucleus-growth layers on a plurality of bonding pads located on a semiconductor chip; growing conductive polymers by allowing nucleus growth on the nucleus-growth layers; attaching the semiconductor chip having the grown conductive polymers to a printed circuit board having a plurality of electrode terminals on one surface thereof such that the bonding pads and the electrode terminals are electrically and mechanically connected to each other by the conductive polymers; and molding one surface of the printed circuit board having the semiconductor chip attached thereto, using an encapsulant.

The conductive polymers are formed to have a size of 50˜500 μm.

Conductive particles are added to the conductive polymers.

The conductive polymer is formed of one selected from the group consisting of organic sulfonic acid, thiophene, pyrrole, a derivative of thiphene, a derivative of pyrrole polyethylene dioxythiophene, and polystyrene sulfonate.

After the step of molding one surface of the printed circuit board using the encapsulant, the method further comprises forming solder balls on a lower surface of the printed circuit board.

In still another aspect, a method for manufacturing a flip chip package comprises the steps of forming a mask on a semiconductor chip having a plurality of bonding pads to expose the bonding pads; forming conductive polymers on the bonding pads exposed through the mask, by screen printing; removing the mask; attaching the semiconductor chip having the formed conductive polymers to a printed circuit board having a plurality of electrode terminals on one surface thereof such that the bonding pads and the electrode terminals are electrically and mechanically connected with each other by means of the conductive polymers; and molding one surface of the printed circuit board having the semiconductor chip attached thereto, using an encapsulant.

The mask is formed of metal or photoresist.

The conductive polymers are formed to have a size of 5˜500 μm, preferably, 50˜200 μm.

Conductive particles are added to the conductive polymers.

The conductive polymer is formed of one selected from the group consisting of organic sulfonic acid, thiophene, pyrrole a derivative of thiphene, a derivative of pyrrole, polyethylene dioxythiophene, and polystyrene sulfonate.

After the step of molding one surface of the printed circuit board using the encapsulant, the method further comprises the step of forming solder balls on a lower surface of the printed circuit board.

### BRIEF DESCRIPTION OF THE DRAWINGS

FIG. 1 is a cross-sectional view illustrating a flip chip package according to the conventional art.

FIG. 2 is a cross-sectional view illustrating a flip chip package in accordance with an embodiment of the present invention.

FIGS. 3A through 3D are cross-sectional views illustrating processes of a method for manufacturing a flip chip package in accordance with another embodiment of the present invention.

FIGS. 4A through 4D are cross-sectional views illustrating processes of a method for manufacturing a flip chip package in accordance with still another embodiment of the present invention.

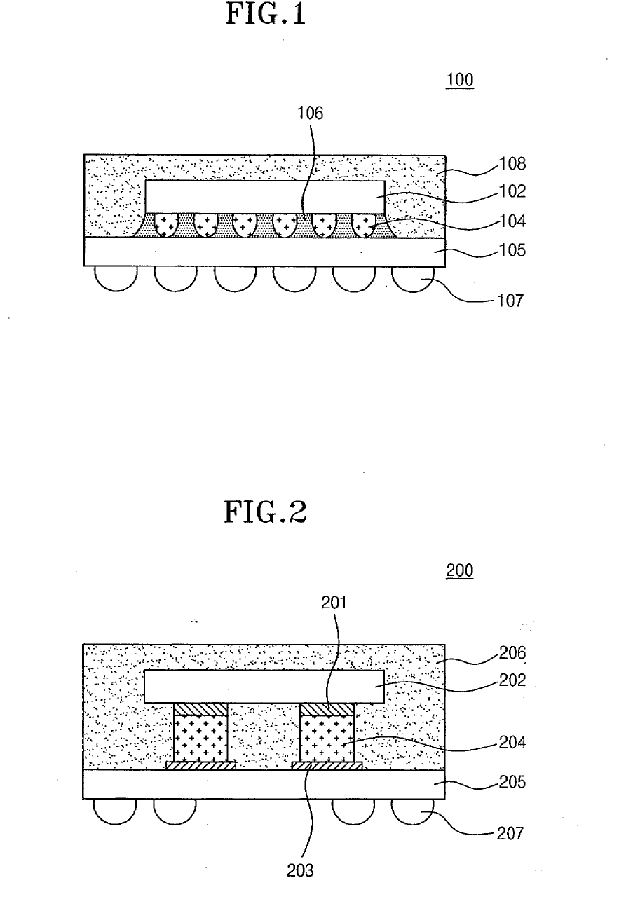

### DESCRIPTION OF SPECIFIC EMBODIMENTS

In the present invention, a flip chip package is manufactured by electrically and mechanically connecting a semiconductor chip and a printed circuit board to each other using conductive polymers.

The flip chip package is constructed by connecting the semiconductor chip to the printed circuit board using the nonmetallic conductive polymers, and crushing or spreading of solder bumps, which are made of a metallic compound according to the conventional art, can be avoided due to the characteristic of the conductive polymers. For example, the conductive polymers have such as excellent returning force. As a result, in the present invention, a flip chip package having a fine pitch can be realized, and the reliability of a bump joint can be improved.

Also, in the present invention, because the conductive polymers are used, an additional process for forming a flux needed to improve the coupling characteristic between solder bumps and the bonding pads of a semiconductor chip or between solder bumps and the electrode terminals of a printed circuit board is not required. Thus, occurrence of defects in other processes can be prevented, whereby it is possible to prevent the cost of a package from increasing and a manufacturing yield from decreasing.

Hereafter, a flip chip package in accordance with an embodiment of the present invention will be described in detail with reference to FIG. 2.

A flip chip package 200 according to the present invention has a construction in which a face-down semiconductor chip 202 having a plurality of bonding pads 201 is attached to a printed circuit board 205 having a plurality of electrode terminals 203 on one surface thereof.

The bonding pads 201 of the semiconductor chip 202 and the electrode terminals 203 of the printed circuit board 205 are electrically and mechanically connected to each other by a medium of conductive polymers 204. One surface of the printed circuit board 205 including the conductive polymers 204 and the semiconductor chip 202 is molded using an encapsulant 206, for example an epoxy molding compound (EMC), such that the semiconductor chip 202 is protected from external stress. Also, a plurality of solder balls 207 serving as mounting members are attached to the lower surface of the printed circuit board 205.

The conductive polymers 204 are made of material which contains a large amount of conductive particles, and are formed to have a size of about 5-500 μm, preferably, 50˜200 μm. For example, the conductive polymer 204 is formed of one selected from the group consisting of polymer containing organic sulfonic acid, polymer containing any one of thiophene, pyrrole and a derivative thereof, polymer containing polyethylene dioxythiophene, and polymer containing polystyrene sulfonate.

In the present invention, since a flip chip package is constructed by electrically and mechanically connecting a semiconductor chip and a printed circuit board to each other using conductive polymers, the reliability of a bump joint can be improved, and difficulties in manufacturing processes can be alleviated.

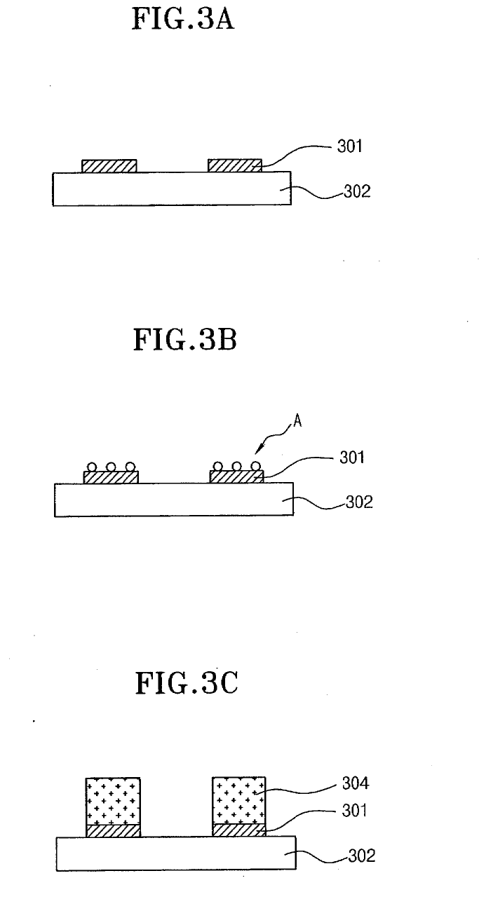

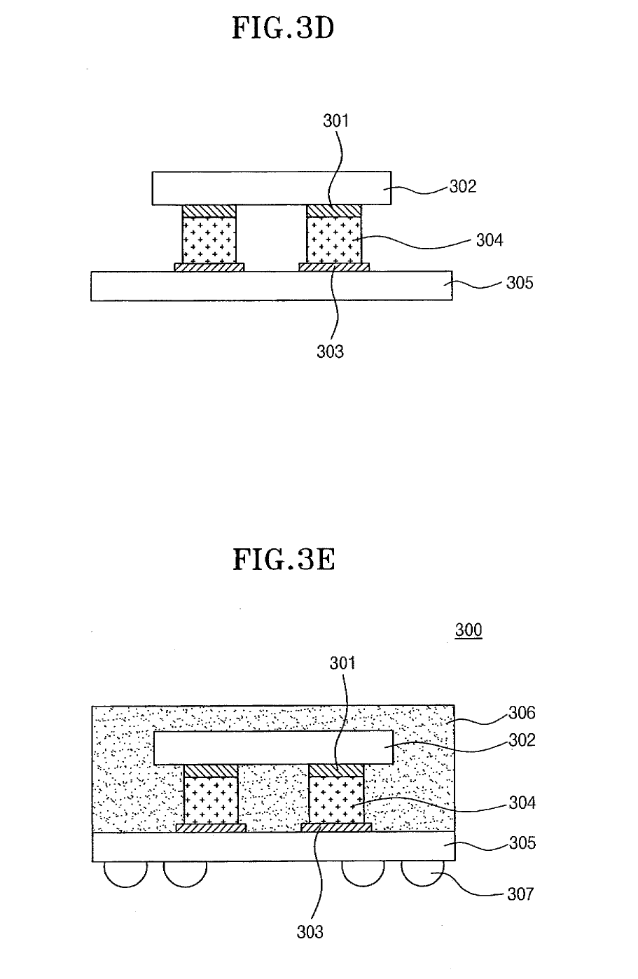

FIGS. 3A through 3D are cross-sectional views illustrating processes of a method for manufacturing a flip chip package in accordance with another embodiment of the present invention.

Referring to FIG. 3A, a semiconductor chip 302 having a plurality of bonding pads 301 on one surface thereof is prepared. Nucleus-growth layers ‘A’ for growing conductive polymers are formed on the respective bonding pads 301 of the semiconductor chip 302.

Referring to FIGS. 3B and 3C, conductive polymers 304 are grown on the nucleus-growth layers ‘A’ to have a predetermined height to thereby perform the same function as conventional bumps. Here, the conductive polymers 304 are grown to have a size of 5-500 μm, preferably, 50˜200 μm while containing a large amount of conductive particles.

For example, the conductive polymer 304 is formed by growing one selected from the group consisting of organic sulfonic acid, thiophene, pyrrole and a derivative of thiphene, a derivative of pyrrole, polymer containing polyethylene dioxythiophene, and polymer containing polystyrene sulfonate.

Referring to FIG. 3D, the semiconductor chip 302 is attached to a printed circuit board 305 having a plurality of electrode terminals 303 which correspond to the bonding pads 301 of the semiconductor chip 302, by the medium of the conductive polymers 304.

Referring to FIG. 3E, one surface of the printed circuit board 305 including the conductive polymers 304 and the semiconductor chip 302 attached by the medium of the conductive polymers 304 is molded by an encapsulant 306 such as an EMC such that the semiconductor chip 302 is protected from external stress. Then, solder balls 307 serving as connection terminals to outside circuits are attached to the lower surface of the printed circuit board 305, by which the manufacture of a flip chip package 300 in accordance with the present embodiment is completed.

In the present invention, since a flip chip package is manufactured using conductive polymers which are not metallic compounds, the reliability of a bump joint can be improved, and a fine pitch can be realized.

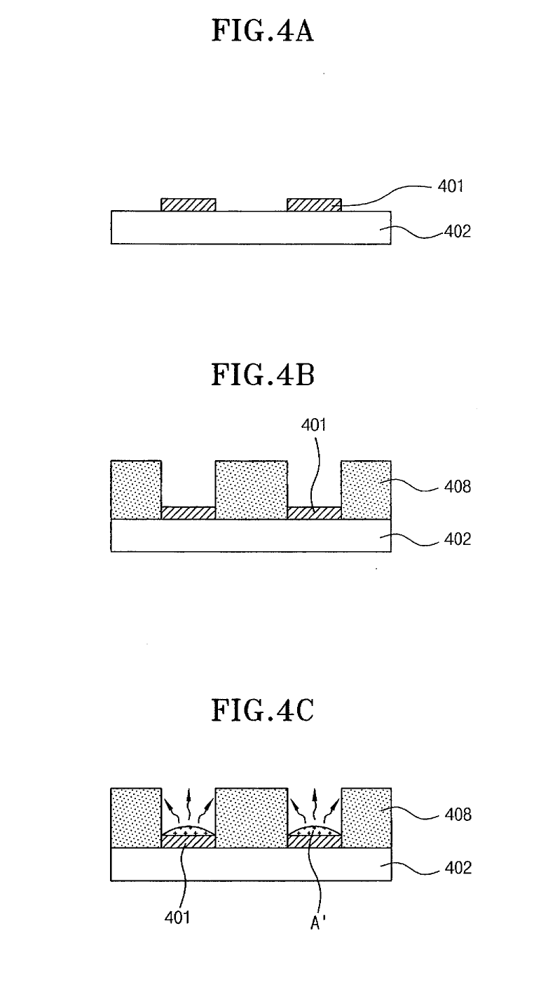

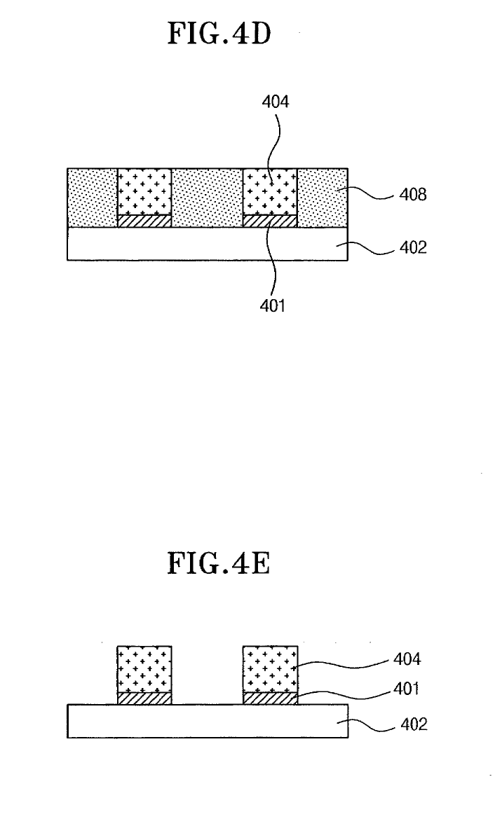

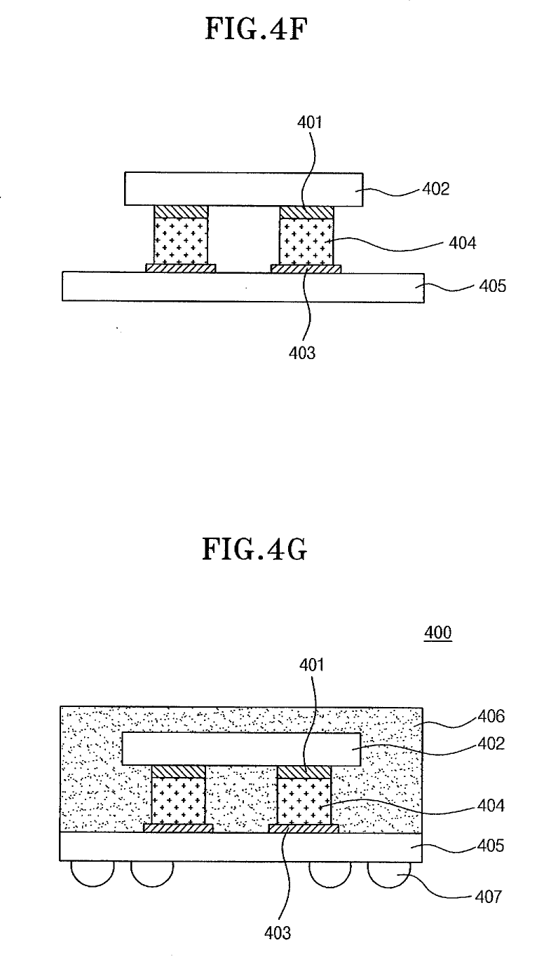

FIGS. 4A through 4D are cross-sectional views illustrating processes of a method for manufacturing a flip chip package in accordance with still another embodiment of the present invention.

Referring to FIGS. 4A and 4B, a semiconductor chip 402 having a plurality of bonding pads 401 on one surface thereof is prepared. A mask 408 is formed on the semiconductor chip 402 to expose the bonding pads 401. The mask 408 is formed of metal or photoresist.

Referring to FIGS. 4C, 4D and 4E, conductive polymers 404, which perform the same function as conventional bumps and have a predetermined shape, are printed, through screen printing, on the bonding pads 401 of the semiconductor chip 402 which are exposed through the mask 408. The conductive polymers 404 are printed to have a size of 5˜500 μm, preferably, 50˜200 μm while containing a large amount of conductive particles therein. The conductive polymer 404 is formed of one selected from the group consisting of organic sulfonic acid, thiophene, pyrrole and a derivative of thiphene, a derivative of pyrrole, polyethylene dioxythiophene, and polystyrene sulfonate.

Referring to FIG. 4F, after removing the mask 408, the semiconductor chip 402 is attached to a printed circuit board 405 having a plurality of electrode terminals 403 which correspond to the bonding pads 401 of the semiconductor chip 402, by the medium of the conductive polymers 404.

Referring to FIG. 4G, one surface of the printed circuit board 405 including the conductive polymers 404 and the semiconductor chip 402 attached by the medium of the conductive polymers 404 is molded by an encapsulant 406 such as an EMC such that the semiconductor chip 402 is protected from external stress. Then, solder balls 407 serving as connection terminals to outside circuits are attached to the lower surface of the printed circuit board 405, by which the manufacture of a flip chip package 400 in accordance with the present embodiment is completed.

In this third embodiment of the present invention, as in the second embodiment, since conductive polymers are formed and a flip chip package is manufactured using the conductive polymers, the same effects as those of the second embodiment can be obtained. In particular, by forming the conductive polymers according to a screen printing method, which is relatively advantageous when compared to a method of growing conductive polymers using growing nuclei, the manufacture of a flip chip package using conductive polymers can be more easily implemented.

While the above-described embodiments of the present invention are illustrated and explained with reference to a chip level, the embodiments of the present invention can be applied to a wafer level to obtain the same effects. Specifically, in the case where the conductive polymers are applied to a wafer level package in place of solder bumps, it is possible to form a package only using the conductive polymers without using underfill material.

As is apparent from the above description, the present invention provides advantages in that, since a semiconductor chip and a printed circuit board are connected with each other using conductive polymers, crushing or spreading of bumps, which are made of a metallic compound according to the conventional art, can be avoided. As a result, in the present invention, the reliability of a bump joint can be improved, and a fine pitch can be realized.

Although a specific embodiment of the present invention has been described for illustrative purposes, those skilled in the art will appreciate that various modifications, additions and substitutions are possible, without departing from the scope and the spirit of the invention as disclosed in the accompanying claims.

What is claimed is:

1. A method for manufacturing a flip chip package, comprising the steps of:
forming nucleus-growth layers on a plurality of bonding pads located on a upper surface of a semiconductor chip;
growing conductive polymers by allowing nucleus growth on the nucleus-growth layers;
attaching the semiconductor chip having the grown conductive polymers to a printed circuit board having a plurality of electrode terminals on one surface thereof such that the bonding pads and the electrode terminals are electrically and mechanically connected to each other the conductive polymers; and
molding one surface of the printed circuit board having the semiconductor chip attached thereto, using an encapsulant.

2. The method according to claim 1, wherein the conductive polymers are formed to have a size of 5-500 μm.

3. The method according to claim 1, wherein the conductive polymers are formed to have a size of 50-200 μm.

4. The method according to claim 1, wherein conductive particles are added to conductive polymers.

5. The method according to claim 1, wherein the conductive polymer comprises one selected from the group consisting of organic sulfonic acid, thiophene, pyrrole and a derivative of thiphene, a derivative of pyrrole, polyethylene dioxythiophene, and polystyrene sulfonate.

6. The method according to claim 1, wherein, after the step of molding one surface of the printed circuit board using the encapsulant, the method further comprises the step of:
forming solder balls on a lower surface of the printed circuit board.

7. A method for manufacturing a flip chip package, comprising the steps of:
forming a mask on a semiconductor chip having a plurality of bonding pads to expose the bonding pads;
forming conductive polymers on the bonding pads exposed through the mask, by screen printing;
removing the mask;
attaching the semiconductor chip having the formed conductive polymers to a printed circuit board having a plurality of electrode terminals on one surface thereof such that the bonding pads and the electrode terminals are electrically and mechanically connected to each other by the conductive polymers; and
molding one surface of the printed circuit board having the semiconductor chip attached thereto, using an encapsulant.

8. The method according to claim 7, wherein the mask is formed of metal or photoresist.

9. The method according to claim 7, wherein the conductive polymers are formed to have a size of 50-500 μm.

10. The method according to claim 7, wherein conductive particles are added to the conductive polymers.

11. The method according to claim 7, wherein the conductive polymer comprises one selected from the group consisting of organic sulfonic acid, thiophene, pyrrole and a derivative of thiphene, a derivative of pyrrole, polyethylene dioxythiophene, and polystyrene sulfonate.

12. The method according to claim 7, wherein, after the step of molding one surface of the printed circuit board using the encapsulant, the method further comprises:
forming solder balls on a lower surface of the printed circuit board.
